(19) United States
(12) Patent Application Publication
(10) Pub. No.: US 2024/0030260 A1
(43) Pub. Date: Jan. 25, 2024

(54) IMAGE SENSOR AND METHOD OF FABRICATING THE SAME

(71) Applicant: SAMSUNG ELECTRONICS CO., LTD., SUWON-SI (KR)

(72) Inventors: Taeyoung Song, Suwon-si (KR); Eun Sub Shim, Suwon-si (KR)

(21) Appl. No.: 18/112,202

(22) Filed: Feb. 21, 2023

(30) Foreign Application Priority Data
Jul. 20, 2022 (KR) 10-2022-0089332

(51) Int. Cl. H01L 27/146

(52) U.S. Cl. CPC H01L 27/1463; H01L 27/14645; H01L 27/14614; H01L 27/14621; H01L 27/14627; H01L 27/14636; H01L 27/14689

(57) ABSTRACT

A method of fabricating an image sensor includes providing a semiconductor substrate, forming a trench in the semiconductor substrate to define pixel regions, doping the trench with dopants of a first conductivity type, doping the trench with dopants of a second conductivity type after doping the trench with dopants of the first conductivity type, forming an insulating liner pattern in the trench after the doping of the trench, performing a first thermal treatment process on the semiconductor substrate after forming the insulating liner pattern, and forming a filling pattern filling an inner space of the trench after performing the first thermal treatment process. A diffusion coefficient of the dopants of the first conductivity type is greater than a diffusion coefficient of the dopants of the second conductivity type. The first thermal treatment process diffuses the dopants of the first and second conductivity types into the semiconductor substrate simultaneously.

### CROSS-REFERENCE TO RELATED APPLICATIONS

This application claims priority under 35 U.S.C. § 119 to Korean Patent Application No. 10-2022-0089332, filed on Jul. 20, 2022 in the Korean Intellectual Property Office, the disclosure of which is incorporated by reference in its entirety herein.

### 1. TECHNICAL FIELD

The present disclosure relates to an image sensor and a method of fabricating the same, and in particular, to an image sensor with increased electrical and optical characteristics and a method of fabricating the same.

### 2. DISCUSSION OF RELATED ART

An image sensor is a device that converts optical signals into electrical signals. With the development of the computer and communications industries, there has been an increasing demand for high-performance image sensors in a variety of applications such as digital cameras, camcorders, personal communication systems, gaming machines, security cameras, micro-cameras for medical applications, and/or robots.

Image sensors are generally classified into charge-coupled device (CCD) and complementary metal-oxide semiconductor (CMOS) image sensors. The CMOS image sensor may be operated in a simplified manner. Additionally, since signal-processing circuits of the CMOS image sensor can be integrated on a single chip, it is possible to reduce a size of a product that the CMOS image sensor is applied to. In addition, since the CMOS image sensor may be operated with a relatively low power consumption, the CMOS image sensor can be applied to an electronic device having a limited battery capacity. Furthermore, since the CMOS image sensor can be fabricated using the existing CMOS fabrication techniques, it is possible to reduce a manufacturing cost thereof. The use of CMOS image sensors is rapidly increasing due to CMOS image sensors having an increased resolution.

### SUMMARY

An embodiment of the present inventive concept provides an image sensor with increased electrical and optical characteristics.

An embodiment of the present inventive concept provides a method of fabricating an image sensor with increased electrical and optical characteristics.

According to an embodiment of the present inventive concept, a method of fabricating an image sensor includes providing a semiconductor substrate. A trench is formed in the semiconductor substrate to define pixel regions. The trench is doped with dopants of a first conductivity type. The trench is doped with dopants of a second conductivity type after the doping of the trench with the dopants of the first conductivity type. An insulating liner pattern is formed in the trench after the doping of the trench with the dopants of the first and second conductivity types. A first thermal treatment process is performed on the semiconductor substrate after the forming of the insulating liner pattern. A filling pattern is formed to fill an inner space of the trench after performing the first thermal treatment process. A diffusion coefficient of the dopants of the first conductivity type is greater than a diffusion coefficient of the dopants of the second conductivity type. The first thermal treatment process diffuses the dopants of the first and second conductivity types into the semiconductor substrate simultaneously.

According to an embodiment of the present inventive concept, an image sensor includes a semiconductor substrate including first and second potential barrier regions and a photoelectric conversion region. A pixel isolation structure is disposed in the semiconductor substrate to define a plurality of pixel regions. The pixel isolation structure includes a filling pattern vertically penetrating the semiconductor substrate. An insulating liner pattern is disposed between the filling pattern and the semiconductor substrate. The first potential barrier region is of a first conductivity type. The second potential barrier region and the photoelectric conversion region are of a second conductivity type. The first potential barrier region is positioned closer to the pixel isolation structure than the second potential barrier region. Dopants of the first conductivity type have a diffusion coefficient that is less than dopants of the second conductivity type.

According to an embodiment of the present inventive concept, an image sensor includes a semiconductor substrate having a first surface and a second surface that are opposite to each other, and comprising a light-receiving region, a light-blocking region, and a pad region. A pixel isolation structure is disposed in the semiconductor substrate and in the light-receiving region and the light-blocking region to define a plurality of pixel regions. The pixel isolation structure comprises a filling pattern vertically penetrating the semiconductor substrate, an insulating liner pattern interposed between the filling pattern and the semiconductor substrate, and an insulating gap-fill pattern on the filling pattern. A transfer gate electrode includes a first portion disposed directly on the first surface of the semiconductor substrate, and at least one second portion that extends from the first portion towards the second surface of the semiconductor substrate and is located in the semiconductor substrate. Photoelectric conversion regions are disposed in the light-receiving region and the light-blocking region and in the plurality of pixel regions of the semiconductor substrate. A back-side contact plug is disposed in a portion of the light-blocking region and is positioned adjacent to the second surface of the semiconductor substrate and is in direct contact with a portion of the filling pattern. A conductive pad is disposed in the pad region and on the second surface of the semiconductor substrate. Color filters are disposed on the second surface of the semiconductor substrate to correspond to the plurality of pixel regions. Micro lenses are on the color filters. The semiconductor substrate comprises a first potential barrier region of a first conductivity type and a second potential barrier region of a second conductivity type. A diffusion coefficient of dopants of the first conductivity type is less than a diffusion coefficient of dopants of the second conductivity type.

### BRIEF DESCRIPTION OF THE DRAWINGS

FIG. 1 is a block diagram illustrating an image sensor according to an embodiment of the present inventive concept.

FIGS. 2A and 2B are circuit diagrams illustrating a unit pixel of an image sensor according to embodiments of the present inventive concept.

FIG. 3 is a plan view illustrating an image sensor according to an embodiment of the present inventive concept.

FIG. 4 is a cross-sectional view, taken along a line A-A′ of FIG. 3, illustrating an image sensor according to an embodiment of the present inventive concept.

FIG. 5 is an enlarged cross-sectional view illustrating a portion ‘A’ of FIG. 4 according to an embodiment of the present inventive concept.

FIG. 6 is a graph showing a doping profile in a region taken along a line B-B′ of FIG. 5 according to an embodiment of the present inventive concept.

FIG. 7 is a graph showing a potential profile in the region taken along the line B-B′ of FIG. 5 according to an embodiment of the present inventive concept.

FIGS. 8, 9, and 10 are cross-sectional views, taken along the line A-A′ of FIG. 3, illustrating an image sensor according to embodiments of the present inventive concept.

FIG. 11 is a flow chart illustrating a method of forming a pixel isolation structure, that is provided in an image sensor according to an embodiment of the present inventive concept.

FIGS. 12A to 12H are cross-sectional views, taken along the line A-A′ of FIG. 3, illustrating a method of fabricating an image sensor according to embodiments of the present inventive concept.

FIG. 13 is a schematic plan view illustrating an image sensor including a semiconductor device according to an embodiment of the present inventive concept.

FIGS. 14 and 15 are cross-sectional views, taken along a line C-C′ of FIG. 13, illustrating an image sensor according to embodiments of the present inventive concept.

### DETAILED DESCRIPTION OF EMBODIMENTS

Example embodiments of the present inventive concepts will now be described more fully with reference to the accompanying drawings, in which example embodiments are shown. Like reference numerals in the drawings denote like elements, and thus a repeated description will be omitted for economy of description.

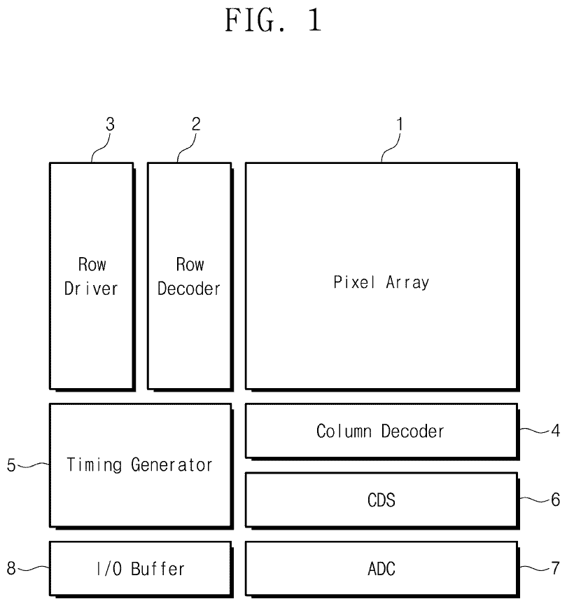

FIG. 1 is a block diagram illustrating an image sensor according to an embodiment of the present inventive concept.

Referring to FIG. 1, an image sensor may include an active pixel sensor array 1, a row decoder 2, a row driver 3, a column decoder 4, a timing generator 5, a correlated double sampler (CDS) 6, an analog-to-digital converter (ADC) 7, and an input/output (I/O) buffer 8.

In an embodiment, the active pixel sensor array 1 may include a plurality of unit pixels that are arranged two-dimensionally to convert optical signals to electrical signals. The active pixel sensor array 1 may be driven by a plurality of driving signals, such as a pixel selection signal, a reset signal, and a charge transmission signal, which are transmitted from the row driver 3. The converted electrical signal may be provided to the CDS 6.

The row driver 3 may be configured to provide the driving signals for driving the plurality of unit pixels to the active pixel sensor array 1, based on the result decoded by the row decoder 2. In an embodiment in which the unit pixels are arranged in a matrix shape (e.g., in rows and columns), the driving signals may be provided to respective rows.

The timing generator 5 may be configured to provide timing and control signals to the row decoder 2 and the column decoder 4.

The CDS 6 may be configured to receive the electric signals generated in the active pixel sensor array 1 and to perform a holding and sampling operation on the received electric signals. For example, in an embodiment the CDS 6 may perform a double sampling operation on a specific noise level and a signal level of the electric signal and may output a difference level corresponding to a difference between the noise and signal levels.

The ADC 7 may be configured to convert analog signals, which correspond to the difference level output from the CDS 6, into digital signals.

The I/O buffer 8 may be configured to latch the digital signal and to sequentially output the latched digital signals to an image signal processing unit based on the result decoded by the column decoder 4.

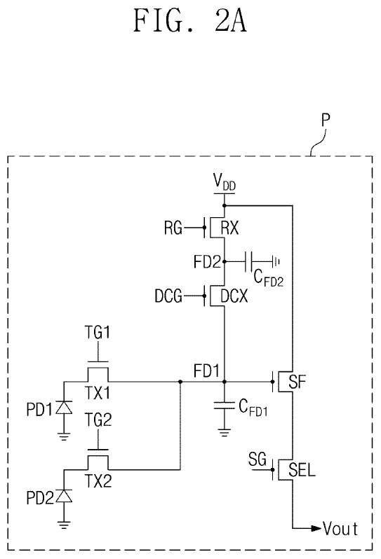

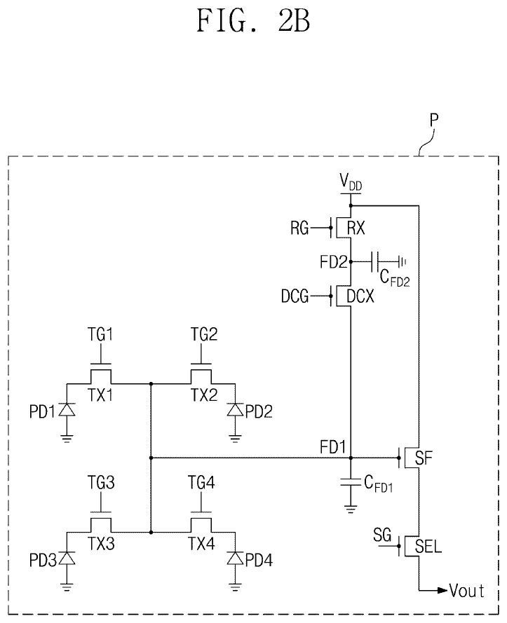

FIGS. 2A and 2B are circuit diagrams illustrating a unit pixel of an image sensor according to embodiments of the present inventive concept.

Referring to FIG. 2A, a unit pixel P may include a photoelectric conversion circuit and a pixel circuit.

The photoelectric conversion circuit may include a plurality of photoelectric conversion devices, a plurality of transfer transistors, and a floating diffusion region FD. As an example, the photoelectric conversion circuit may include first and second photoelectric conversion devices PD1 and PD2, first and second transfer transistors TX1 and TX2, and a first floating diffusion region FD1, which is connected in common to the first and second transfer transistors TX1 and TX2.

The pixel circuit may include a reset transistor RX, a source follower transistor SF, a selection transistor SEL, and a double conversion gain transistor DCX. In an embodiment, each of the unit pixels P is illustrated to include four pixel transistors. However, embodiments of the present inventive concept are not necessarily limited thereto. For example, the number of the pixel transistors PTR in each of the unit pixels P may be variously changed.

In an embodiment, the first and second photoelectric conversion devices PD1 and PD2 may be configured to generate electric charges in response to an incident light, and in this embodiment, the generated electric charges may be accumulated in the first and second photoelectric conversion devices PD1 and PD2. In an embodiment, the first and second photoelectric conversion devices PD1 and PD2 may be, for example, a photodiode, a phototransistor, a photo gate, a pinned photodiode (PPD), and combinations thereof.

The first and second transfer transistors TX1 and TX2 may be configured to transfer the electric charges, which are stored in the first and second photoelectric conversion devices PD1 and PD2, to the first floating diffusion region FD1. The first and second transfer transistors TX1 and TX2 may be controlled by first and second transfer signals TG1 and TG2. The first and second transfer transistors TX1 and TX2 may share the first floating diffusion region FD1.

The first floating diffusion region FD1 may be configured to receive the electric charges, which are generated in the first or second photoelectric conversion device PD1 or PD2, and to cumulatively store the electric charges. The source follower transistor SF may be controlled by an amount of the photocharges stored in the first floating diffusion region FD1.

The reset transistor RX may reset electric charges, which are stored in the first floating diffusion region FD1 and a second floating diffusion region FD2, periodically in response to a reset signal applied to a reset gate electrode RG. In an embodiment, the reset transistor RX may include a drain terminal, which is connected to the double conversion gain transistor DCX, and a source terminal, which is connected to a pixel power voltage VPIX. If the reset transistor RX and the double conversion gain transistor DCX are turned on, the pixel power voltage VPIX may be applied to the first and second floating diffusion regions FD1 and FD2. Accordingly, the electric charges, which are stored in the first and second floating diffusion regions FD1 and FD2, may be discharged, and as a result, the first and second floating diffusion regions FD1 and FD2 may be reset.

The double conversion gain transistor DCX may be provided between the first floating diffusion region FD1 and the second floating diffusion region FD2 to connect them to each other. The double conversion gain transistor DCX may be connected in series to the reset transistor RX through the second floating diffusion region FD2. For example, the double conversion gain transistor DCX may be provided between the first floating diffusion region FD1 and the reset transistor RX to connect them to each other. The double conversion gain transistor DCX may be configured to change a capacitance CFD1 of the first floating diffusion region FD1 in response to a double conversion gain control signal and thereby to change a conversion gain of the unit pixel P.

In an embodiment, during an imaging process, not only a low brightness of light but also a high brightness of light may be incident into a pixel array or not only a high intensity of light but also a low intensity of light may be incident into the pixel array. Accordingly, a conversion gain in each pixel may vary depending on a brightness or intensity of the incident light. For example, when the double conversion gain transistor DCX is turned off, the unit pixel may have a first conversion gain, and when the double conversion gain transistor DCX is turned on, the unit pixel may have a second conversion gain that is higher than the first conversion gain. For example, depending on an operation of the double conversion gain transistor DCX, the conversion gain in a first conversion gain mode (e.g., a high brightness mode) may have a value different from that in a second conversion gain mode (e.g., a low brightness mode).

When the double conversion gain transistor DCX is turned off, the first floating diffusion region FD1 may have a capacitance corresponding to the first capacitance C_{FD1}. When the double conversion gain transistor DCX is turned on, the first floating diffusion region FD1 may be connected to the second floating diffusion region FD2, and a capacitance of the first and second floating diffusion regions FD1 and FD2 may be a sum of first and second capacitance CFD1 and CFD2. For example, when the double conversion gain transistor DCX is turned on, the capacitance of the first or second floating diffusion region FD1 or FD2 may increase to reduce the conversion gain, and when the double conversion gain transistor DCX is turned off, the capacitance of the first floating diffusion region FD1 may decrease to increase the conversion gain.

The source follower transistor SF may be a source follower buffer amplifier that is configured to generate a source-drain current in proportion to a charge amount of the first floating diffusion region FD1 to be input to a source follower gate electrode. The source follower transistor SF may amplify a variation in electric potential of the floating diffusion region FD and may output the amplified signal to an output line Vout through the selection transistor SEL. The source follower transistor SF may include a source terminal that is connected to the pixel power voltage VPIX. The source follower transistor SF may include a drain terminal that is connected to a source terminal of the selection transistor SEL.

The selection transistor SEL may be used to select a row of the unit pixels P to be read out during a read operation. When the selection transistor SEL is turned on by a selection signal SG applied to a selection gate electrode, an electrical signal, that is output to a drain electrode of the source follower transistor SF, may be output to the output line Vout.

Referring to FIG. 2B, the unit pixel P may include the photoelectric conversion circuit and the pixel circuit, and the photoelectric conversion circuit may include the first, second, third, and fourth photoelectric conversion devices PD1, PD2, PD3, and PD4, the first, second, third, and fourth transfer transistors TX1, TX2, TX3, and TX4, and the first floating diffusion region FD1, as described with reference to FIG. 2A. The pixel circuit may include four pixel transistors (e.g., RX, DCX, SF, and SEL), similar to the embodiment of FIG. 2A.

The first to fourth transfer transistors TX1, TX2, TX3, and TX4 may share the first floating diffusion region FD1. Transfer gate electrodes of the first to fourth transfer transistors TX1, TX2, TX3, and TX4 may be controlled by the first to fourth transfer signals TG1, TG2, TG3, and TG4.

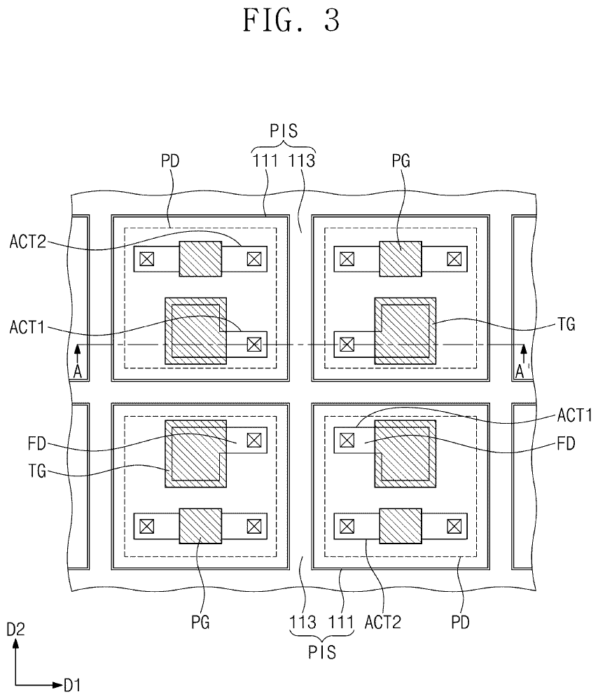

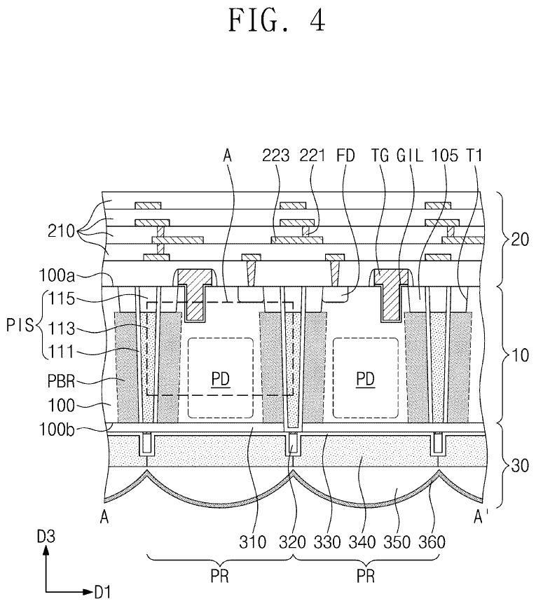

FIG. 3 is a plan view illustrating an image sensor according to an embodiment of the present inventive concept. FIG. 4 is a cross-sectional view, taken along a line A-A′ of FIG. 3, to illustrate an image sensor according to an embodiment of the present inventive concept.

Referring to FIGS. 3 and 4, an image sensor according to an embodiment of the present inventive concept may include a photoelectric conversion layer 10, a readout circuit layer 20, and an optically-transparent layer 30, when viewed in a vertical cross-section.

The photoelectric conversion layer 10 may be disposed between the readout circuit layer 20 and the optically-transparent layer 30 (e.g., in the third direction D3), when viewed in a vertical cross-section. The photoelectric conversion layer 10 may be configured to convert light that is incident from the outside to electrical signals. The photoelectric conversion layer 10 may include a semiconductor substrate 100 and a pixel isolation structure PIS, a potential barrier region PBR, and photoelectric conversion regions PD that are provided in the semiconductor substrate 100.

For example, the semiconductor substrate 100 may have a first or top surface 100a and a second or bottom surface 100b that are opposite to each other (e.g., in the third direction D3). In an embodiment, the semiconductor substrate 100 may be a substrate including a bulk silicon substrate and an epitaxial layer that are sequentially stacked and are of a first conductivity type (e.g., p-type). In an embodiment in which the bulk silicon substrate is removed during a fabrication process of an image sensor, the semiconductor substrate 100 may be composed of only the p-type epitaxial layer. In an embodiment, the semiconductor substrate 100 may be a bulk semiconductor substrate including a well of the first conductivity type.

In each of the pixel regions PR, a device isolation layer 105 may be disposed adjacent to (e.g., immediately adjacent to) the first surface 100a of the semiconductor substrate 100. The device isolation layer 105 may be provided in a first trench T1 that is formed by recessing the first surface 100a of the semiconductor substrate 100. The device isolation layer 105 may be formed of or include an insulating material. In an embodiment, the device isolation layer 105 may include a liner oxide layer and a liner nitride layer that are formed to conformally cover a surface of the first trench T1, and a gap-filling oxide layer that is formed to fill the first trench T1 provided with the liner oxide and nitride layers. The device isolation layer 105 may define an active portion in the semiconductor substrate 100 and near the first surface 100a. In an embodiment, the device isolation layer 105 may define first and second active portions ACT1 and ACT2 in the semiconductor substrate 100. In each of the pixel regions PR, the first and second active portions ACT1 and ACT2 are spaced apart from each other (e.g., in the second direction D2) and may have different sizes from each other.

The pixel isolation structure PIS may be disposed in the semiconductor substrate 100 to define a plurality of the pixel regions PR. The pixel isolation structure PIS may be vertically extended from the first surface 100a of the semiconductor substrate 100 to the second surface 100b. The pixel isolation structure PIS may penetrate a portion of the device isolation layer 105.

The pixel isolation structure PIS may include first portions that are extended in a first direction D1 and parallel to each other, and second portions that are extended in a second direction D2 and parallel to each other to cross the first portions. The pixel isolation structure PIS may enclose each of the pixel regions PR or each of the photoelectric conversion regions PD, when viewed in a plan view.

The pixel isolation structure PIS may have an upper width positioned at a level of the first surface 100a of the semiconductor substrate 100 and may have a lower width positioned at a level of the second surface 100b of the semiconductor substrate 100. In an embodiment, the lower width may be substantially equal to or less than the upper width. In an embodiment, the width of the pixel isolation structure PIS may gradually decrease in a direction from the first surface 100a of the semiconductor substrate 100 towards the second surface 100b. The pixel isolation structure PIS may have a length in a third direction D3. The length of the pixel isolation structure PIS may be substantially equal to a vertical thickness of the semiconductor substrate 100.

The potential barrier region PBR may be provided in a portion of the semiconductor substrate 100 that is adjacent to a side surface of the pixel isolation structure PIS. The potential barrier region PBR may be doped with impurities to have the same conductivity type (e.g., the first conductivity type or p type) as the semiconductor substrate 100 and/or a different conductivity type (e.g., a second conductivity type or n type) from the semiconductor substrate 100. The potential barrier region PBR may be in direct contact with a side surface of an insulating liner pattern 111 of the pixel isolation structure PIS. Electron-hole pairs (EHP) causing a dark current may be generated by a surface defect of the second trench T2 formed during a process of forming the second trench T2. However, the dark current may be reduced by the potential barrier region PBR according to an embodiment of the present inventive concept.

The photoelectric conversion regions PD may be provided in the semiconductor substrate 100 in the pixel regions PR, respectively. The photoelectric conversion regions PD may generate photocharges in proportion to an intensity of an incident light. The photoelectric conversion regions PD may be formed by injecting dopants that are of a second conductivity type different from the semiconductor substrate 100, into the semiconductor substrate 100.

In an embodiment, each of the photoelectric conversion regions PD may have a difference in doping concentration between portions adjacent to the first and second surfaces 100a and 100b, thereby having a non-vanishing gradient in potential between the first and second surfaces 100a and 100b of the semiconductor substrate 100. For example, the photoelectric conversion regions PD may include a plurality of dopant regions which are vertically stacked (e.g., in the third direction D3).

The readout circuit layer 20 may be disposed on the first surface 100a of the semiconductor substrate 100. The readout circuit layer 20 may include readout circuits (e.g., MOS transistors) that are electrically connected to the photoelectric conversion regions PD. For example, the readout circuit layer 20 may include the reset transistor RX, the selection transistor SEL, the double conversion gain transistor DCX, the selection transistor SEL, and the source follower transistor SF, described with reference to embodiments of FIGS. 2A and 2B.

In each of the pixel regions PR, a transfer gate electrode TG may be disposed on the first active portion ACT1 of the semiconductor substrate 100. In an embodiment, the transfer gate electrode TG may be located at a center portion of each pixel region PR, when viewed in a plan view. The transfer gate electrode TG may include a first portion and a second portion. The first portion of the transfer gate electrode TG may be disposed on (e.g., disposed directly thereon) the first surface 100a of the semiconductor substrate 100. The second portion of the transfer gate electrode TG may be extended from the first portion towards the second surface 100b of the semiconductor substrate 100 and may be disposed in the semiconductor substrate 100. In an embodiment, when viewed in a vertical cross-section, the transfer gate electrode TG may have a T-shaped structure. A gate insulating layer GIL may be interposed between the transfer gate electrode TG and the semiconductor substrate 100.

The floating diffusion region FD may be provided in a portion of the first active portion ACT1 located at a side of the transfer gate electrode TG (e.g., in the first direction D1). The floating diffusion region FD may be formed by injecting dopants into the semiconductor substrate 100 and may have a conductivity type different from that of the semiconductor substrate 100. For example, in an embodiment the floating diffusion region FD may be an n-type dopant region.

In each of the pixel regions PR, at least one pixel transistor may be provided on the second active portion ACT2. The pixel transistor that is provided in each pixel region PR may be one of the reset transistor RX, the source follower transistor SF, the double conversion gain transistor DCX, and the selection transistor SEL described with reference to embodiments of FIGS. 2A and 2B. The pixel transistor may include a pixel gate electrode PG, which is arranged to cross the second active portion ACT2, and source/drain regions, which are disposed in portions of the second active portion ACT2 located at both sides of the pixel gate electrode PG. The pixel gate electrode PG may have a bottom surface that is parallel to a top surface of the second active portion ACT2. In an embodiment, the pixel gate electrode PG may be formed of or include at least one of, for example, doped polysilicon, metallic materials, conductive metal nitrides, conductive metal silicide materials, conductive metal oxide materials, or combinations thereof. However, embodiments of the present disclosure are not necessarily limited thereto.

Interlayer insulating layers 210 may be disposed on the first surface 100a of the semiconductor substrate 100 to cover the transfer gate electrode TG.

An interconnection structure that is connected to the readout circuits, may be disposed in the interlayer insulating layers 210. The interconnection structure may include metal lines 223 and contact plugs 221 connecting the metal lines 223 to each other.

The optically-transparent layer 30 may be disposed on (e.g., disposed directly thereon) the second surface 100b of the semiconductor substrate 100. The optically-transparent layer 30 may include a planarization insulating layer 310, a lattice structure 320, a protection layer 330, color filters 340, micro lenses 350, and a passivation layer 360. The optically-transparent layer 30 may be configured to perform an operation of focusing and filtering light that is incident from the outside, and to provide the light to the photoelectric conversion layer 10.

In an embodiment, the planarization insulating layer 310 may cover the second surface 100b of the semiconductor substrate 100. The planarization insulating layer 310 may be formed of a transparent insulating material and may include a plurality of layers. The planarization insulating layer 310 may be formed of an insulating material having a refractive index that is different from the semiconductor substrate 100. In an embodiment, the planarization insulating layer 310 may be formed of or include at least one of metal oxide and/or silicon oxide. However, embodiments of the present inventive concept are not necessarily limited thereto.

The lattice structure 320 may be disposed on the planarization insulating layer 310. When viewed in a plan view, the lattice structure 320 may have a lattice shape, similar to the pixel isolation structure PIS. The lattice structure 320 may be overlapped with the pixel isolation structure PIS, when viewed in a plan view. For example, the lattice structure 320 may include first portions that are extended in the first direction D1, and second portions that are extended in the second direction D2 to cross the first portions. In an embodiment, a width of the lattice structure 320 may be substantially equal to or less than the smallest width of the pixel isolation structure PIS.

The lattice structure 320 may include a light-blocking pattern and/or a low refractive pattern. In an embodiment, a light-blocking pattern may be formed of or include at least one of metallic materials (e.g., titanium, tantalum, or tungsten). The low refractive pattern may be formed of or include a material having a refractive index that is lower than the light-blocking pattern. The low refractive pattern may be formed of an organic material and may have a refractive index in a range of about 1.1 to about 1.3. For example, the lattice structure 320 may be a polymer layer including silica nano-particles.

The protection layer 330 may be disposed on the planarization insulating layer 310 to cover a surface of the lattice structure 320 conformally (e.g., to a substantially uniform thickness). In an embodiment, the protection layer 330 may be a single-layer or multi-layered structure including at least one of an aluminum oxide layer and a silicon carbon oxide layer.

In an embodiment, the color filters 340 may be formed to correspond to the pixel regions PR, respectively. For example, the color filters 340 may be disposed to fill empty regions defined by the lattice structure 320. In an embodiment, the color filters 340 may include red, green, or blue color filters or magenta, cyan, or yellow color filters having colors that are determined based on positions of the unit pixels. However, embodiments of the present inventive concept are not necessarily limited thereto and the colors of the color filters 340 may vary.

The micro lenses 350 may be disposed on (e.g., disposed directly thereon) the color filters 340. The micro lenses 350 may have a convex shape and may have a specific curvature radius. The micro lenses 350 may be formed of or include an optically transparent resin.

The passivation layer 360 may be formed to conformally cover the surfaces of the micro lenses 350. In an embodiment, the passivation layer 360 may include at least one of, for example, inorganic oxide materials.

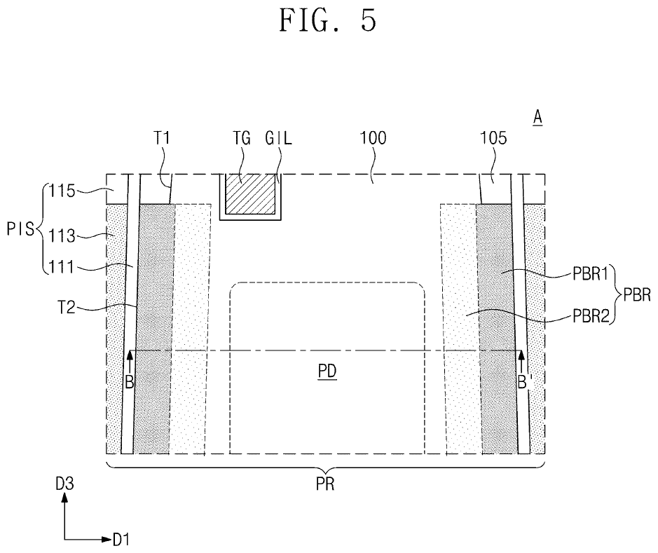

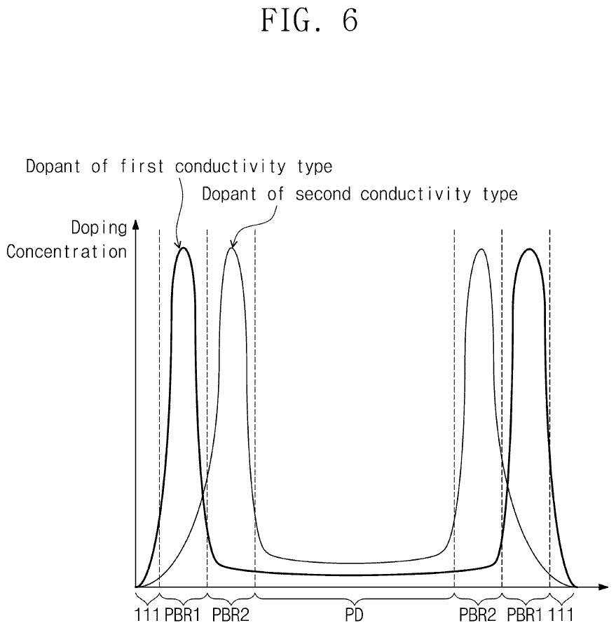

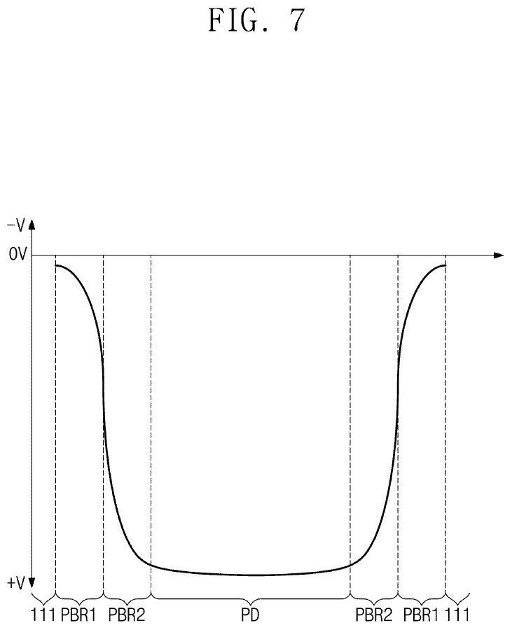

FIG. 5 is an enlarged cross-sectional view illustrating a portion ‘A’ of FIG. 4. FIG. 6 is a graph showing a doping profile in a region taken along a line B-B′ of FIG. 5. FIG. 7 shows that a region taken along the line B-B′ of FIG. 5 has a potential well.

In the following description, an element previously described with reference to FIGS. 3 and 4 may be identified by the same reference number without repeating an overlapping description thereof, for concise description.

Referring to FIG. 5, the pixel isolation structure PIS may be disposed in the second trench T2 which is formed in the semiconductor substrate 100. The pixel isolation structure PIS may include an insulating liner pattern 111, a filling pattern 113, and an insulating gap-fill pattern 115. In an embodiment, the pixel isolation structure PIS may have an aspect ratio in a range of about 10:1 to about 15:1.

The insulating liner pattern 111 may be disposed between the filling pattern 113 and the potential barrier region PBR of the semiconductor substrate 100. The insulating liner pattern 111 may be in direct contact with the potential barrier region PBR of the semiconductor substrate 100. The insulating liner pattern 111 may have a refractive index lower than the semiconductor substrate 100. For example, in an embodiment the insulating liner pattern 111 may be formed of or include at least one of silicon-based insulating materials (e.g., silicon nitride, silicon oxide, and/or silicon oxynitride) and/or high-k dielectric materials (e.g., hafnium oxide and/or aluminum oxide). In an embodiment, the insulating liner pattern 1 may include a plurality of layers, which are formed of or include different materials. In an embodiment, the insulating liner pattern 111 may have a thickness in a range of about 30 Å to about 350 Å.

When viewed in the plan view of FIG. 3, each of the insulating liner patterns 111 may be arranged to enclose a corresponding one of the pixel regions PR (e.g., in the first and second directions D1, D2). The insulating liner patterns 111 may be spaced apart from each other.

The filling pattern 113 in the semiconductor substrate 100 may be provided as a single body. For example, the filling pattern 113 may be composed of a single layer. Referring to FIG. 3, the filling pattern 113 may include first portions that are extended in the first direction D1 and parallel to each other, and second portions that are extended in the second direction D2 and parallel to each other to cross the first portions. The filling pattern 113 may be continuously extended in the first and second directions D1 and D2.

The insulating liner pattern 111 and the filling pattern 113 may include dopants of the first conductivity type. For example, in an embodiment the dopants of the first conductivity type may include at least one compound selected from boron (B), gallium (Ga), indium (In), or aluminum (Al).

The insulating gap-fill pattern 115 may be disposed on (e.g., disposed directly thereon) a top surface of the filling pattern 113 and may have a top surface that is located at substantially the same level as (e.g., is coplanar with) a top surface of the device isolation layer 105. A bottom surface of the insulating gap-fill pattern 115 may be located at a level that is less than or equal to a bottom surface of the device isolation layer 105.

The bottom surface of the insulating gap-fill pattern 115 may have a rounded shape. In an embodiment, the insulating gap-fill pattern 115 may be formed of or include at least one of silicon oxide, silicon oxynitride, or silicon nitride.

The potential barrier region PBR may include a first potential barrier region PBR1 and a second potential barrier region PBR2. The first potential barrier region PBR1 may be in direct contact with the insulating liner pattern 111. The second potential barrier region PBR2 may be spaced apart from the insulating liner pattern 111 and may be in direct contact with the first potential barrier region PBR1. For example, the first potential barrier region PBR1 may be positioned between the second potential barrier region PBR2 and the insulating liner pattern 111. Thus, the first potential barrier region PBR1 may be positioned closer to the pixel isolation structure PIS than the second potential barrier region PBR2.

The first potential barrier region PBR1 may have a conductivity type that is different from a conductivity type of the second potential barrier region PBR2. For example, the first potential barrier region PBR1 may include dopants of the first conductivity type (e.g., p-type). The second potential barrier region PBR2 may include dopants of the second conductivity type (e.g., n-type).

The dopants in the first potential barrier region PBR1 may have a diffusion coefficient that is less than (e.g., smaller than) a diffusion coefficient of the dopants in the second potential barrier region PBR2. Thus, in an embodiment in which a thermal treatment process is performed in a subsequent step of the fabrication process, the dopants, which are of the second conductivity type and have a high diffusion coefficient, may be diffused into a deeper region in the first direction D1, compared with the dopants of the first conductivity type. The first and second potential barrier regions PBR1 and PBR2 may be formed, due to this difference in diffusion coefficients between the dopants of the first and second conductivity types. For example, the dopants of the first conductivity type may be gallium (Ga), and the dopants of the second conductivity type may be phosphorus (P).

Referring to FIGS. 6 and 7, in the photoelectric conversion region PD of the semiconductor substrate 100, a doping concentration of the dopants of the first conductivity type (e.g., p-type) may be lower than a doping concentration of the dopants of the second conductivity type (e.g., n-type). The doping concentration of the dopants of the first conductivity type may have the highest value in the first potential barrier region PBR1. The doping concentration of the dopants of the second conductivity type may have the highest value in the second potential barrier region PBR2. The highest value of the doping concentration of the dopants of the first conductivity type in the first potential barrier region PBR1 may be equal to or different from the highest value of the doping concentration of the dopants of the second conductivity type in the second potential barrier region PBR2. The doping concentration of the dopants of the second conductivity type in the second potential barrier region PBR2 may be in a range of about 1,000 to about 10,000 times the doping concentration of the dopants of the second conductivity type in the photoelectric conversion region PD.

For example, in an embodiment the first potential barrier region PBR1 may be formed of a p-type semiconductor material, and the second potential barrier region PBR2 may be formed of an n-type semiconductor material. The second potential barrier region PBR2 may be positioned closer to the photoelectric conversion region PD than the first potential barrier region PBR1. A junction may be formed between the first and second potential barrier regions PBR1 and PBR2. The potential may be highest between the first potential barrier region PBR1 and the insulating liner pattern 111 and may have an abrupt decrease between the first potential barrier region PBR1 and the second potential barrier region PBR2. Thus, a potential well, which is deep and has a wide lower portion, may be formed in a structure including the first and second potential barrier regions PBR1 and PBR2 and the photoelectric conversion region PD. Accordingly, a full well capacity (FWC) or a maximally storable charge amount of each pixel region PR may be increased. That is, a dynamic range of the image sensor may be increased.

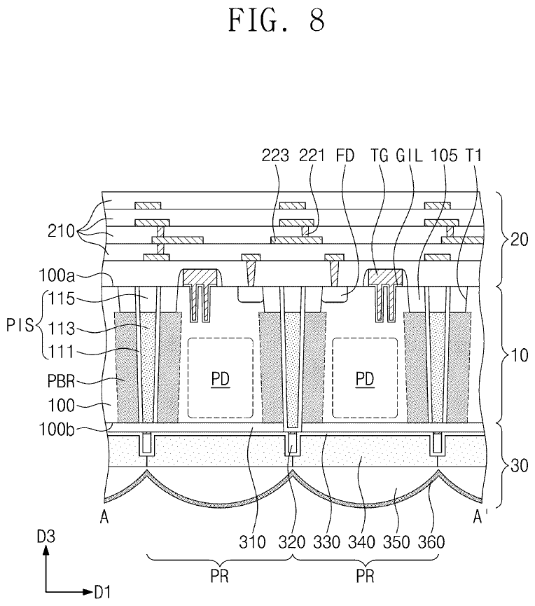

FIGS. 8, 9, and 10 are cross-sectional views, each of which is taken along the line A-A′ of FIG. 3 to illustrate an image sensor according to an embodiment of the present inventive concept.

In the following description, an element previously described with reference to FIGS. 3 and 4 may be identified by the same reference number without repeating an overlapping description thereof, for concise description.

Referring to FIG. 8, the transfer gate electrode TG may include a first portion, which is disposed on (e.g., disposed directly thereon) the first surface 100a of the semiconductor substrate 100, and a second portion, which is extended from the first portion into the semiconductor substrate 100. In an embodiment, the transfer gate electrode TG may include a plurality of second portions. For example, the transfer gate electrode TG may include two second portions. However, embodiments of the present inventive concept are not necessarily limited thereto and the transfer gat electrode TG may have various numbers of second portions. In an embodiment in which the transfer gate electrode TG has a plurality of second portions, it may be possible to increase a charge driving ability of the transfer transistor and thereby to increase performance of the image sensor. The gate insulating layer GIL may be located between the transfer gate electrode TG and the semiconductor substrate 100. For example, the gate insulating layer GIL may enclose the second portions of the transfer gate electrode TG.

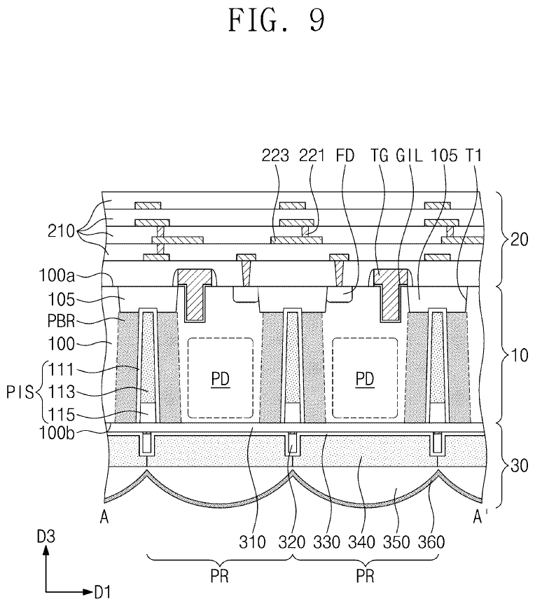

Referring to FIG. 9, the pixel isolation structure PIS may have a first width near the first surface 100a of the semiconductor substrate 100 and a second width that is larger than the first width near the second surface 100b of the semiconductor substrate 100. Furthermore, a width of the pixel isolation structure PIS may increase gradually as a distance from the first surface 100a of the semiconductor substrate 100 increases in a direction towards the second surface 100b.

The pixel isolation structure PIS may include the insulating liner pattern 111, the filling pattern 113, and the insulating gap-fill pattern 115, as described above.

The pixel isolation structure PIS may be in direct contact with the device isolation layer 105. As an example, a portion of the insulating liner pattern 111 of the pixel isolation structure PIS may be in direct contact with the device isolation layer 105. A portion of the insulating liner pattern 111 may be disposed between the device isolation layer 105 and the filling pattern 113.

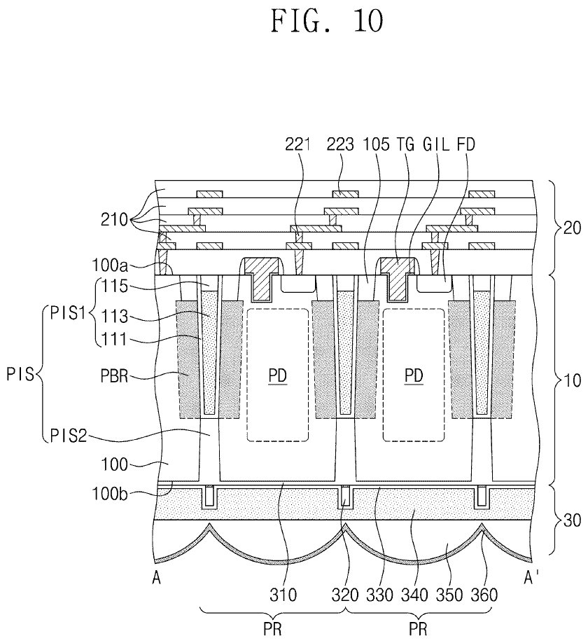

Referring to FIG. 10, the pixel isolation structure PIS may include first and second pixel isolation structures PIS1 and PIS2. In an embodiment, the first pixel isolation structure PIS1 may have substantially the same features as the pixel isolation structure PIS previously described with embodiments shown in FIGS. 3 and 4. A portion of the insulating liner pattern 111 may be in direct contact with the second pixel isolation structure PIS2 and may be disposed between the second pixel isolation structure PIS2 and the filling pattern 113.

The second pixel isolation structure PIS2 may have substantially the same planar structure as the first pixel isolation structure PIS1. The second pixel isolation structure PIS2 may be overlapped with the first pixel isolation structure PIS1, when viewed in a plan view. For example, the second pixel isolation structure PIS2 may include first portions that are extended in the first direction D1 and second portions that are extended in the second direction D2 to cross the first portions.

The second pixel isolation structure PIS2 may be extended from the second surface 100b of the semiconductor substrate 100 in a vertical direction (e.g., the third direction D3) and may be disposed in the semiconductor substrate 100. The second pixel isolation structure PIS2 may be disposed in a trench that is recessed from the second surface 100b of the semiconductor substrate 100.

The second pixel isolation structure PIS2 may have a bottom surface that is located between the first and second surfaces 100a and 100b of the semiconductor substrate 100. For example, the second pixel isolation structure PIS2 may be spaced apart from the first surface 100a of the semiconductor substrate 100. The second pixel isolation structure PIS2 may be in direct contact with the first pixel isolation structure PIS1. For example, an upper surface of the second pixel isolation structure PIS2 may directly contact a lower surface of the first pixel isolation structure PIS1. The width of the second pixel isolation structure PIS2 may gradually decrease as a distance from the second surface 100b of the semiconductor substrate 100 increases in a direction towards the first surface 100a.

When measured in the vertical direction D3, a length of the second pixel isolation structure PIS2 may be different from a length of the first pixel isolation structure PIS1. for example, in an embodiment, the length of the second pixel isolation structure PIS2 may be less than or substantially equal to the length of the first pixel isolation structure PIS1.

The second pixel isolation structure PIS2 may include at least one of high-k dielectric materials having dielectric constants that are higher than that of the silicon oxide layer. In an embodiment, the second pixel isolation structure PIS2 may be formed of metal oxide or metal fluoride containing at least one metallic element that is selected from the group consisting of hafnium (Hf), zirconium (Zr), aluminum (Al), tantalum (Ta), titanium (Ti), yttrium (Y), and lanthanum (La). For example, the second pixel isolation structure PIS2 may include an aluminum oxide layer and a hafnium oxide layer that are sequentially stacked (e.g., in the third direction D3).

In an embodiment, the potential barrier region PBR may be disposed on a side surface of the first pixel isolation structure PIS1 but not on a side surface of the second pixel isolation structure PIS2. However, embodiments of the present inventive concept are not necessarily limited thereto. For example, in an embodiment the potential barrier region PBR may be disposed on the side surfaces of both of the first and second pixel isolation structures PIS1 and PIS2.

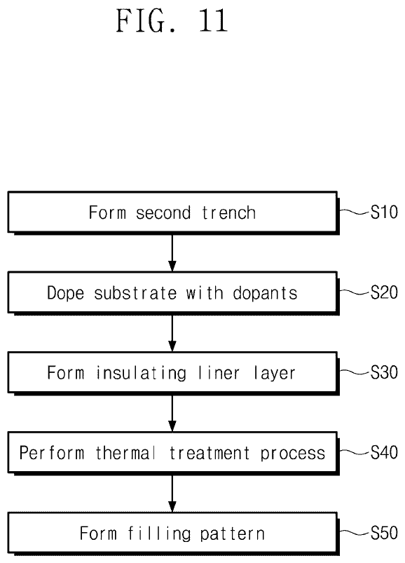

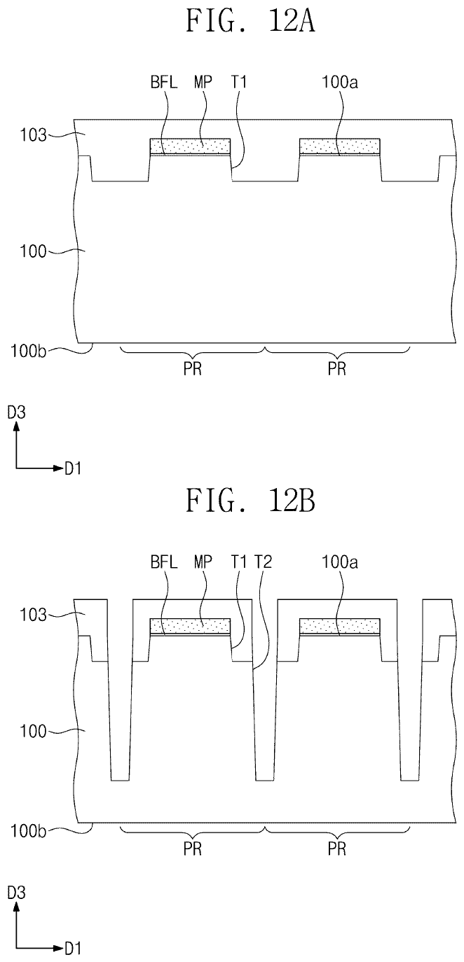

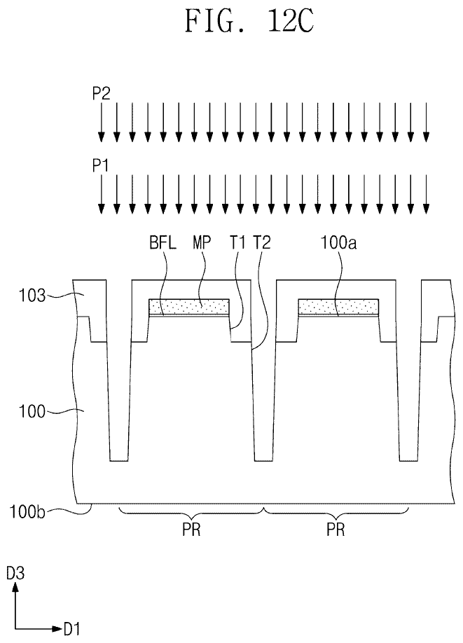

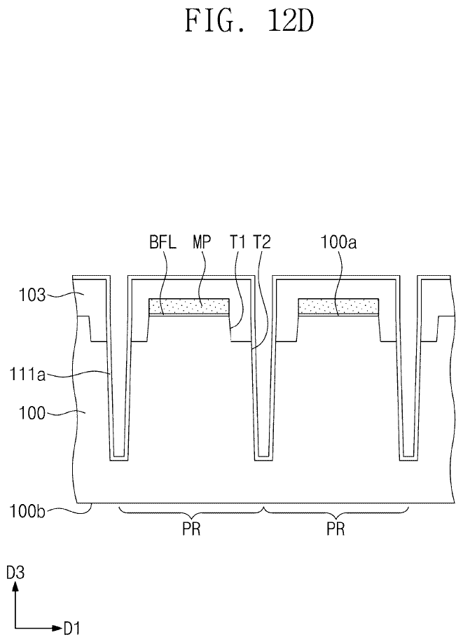

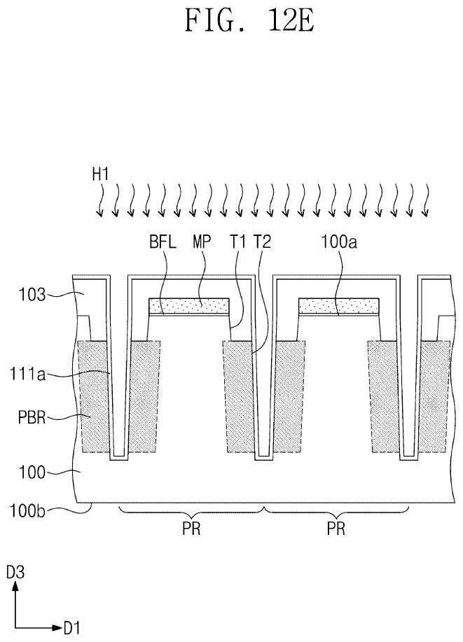

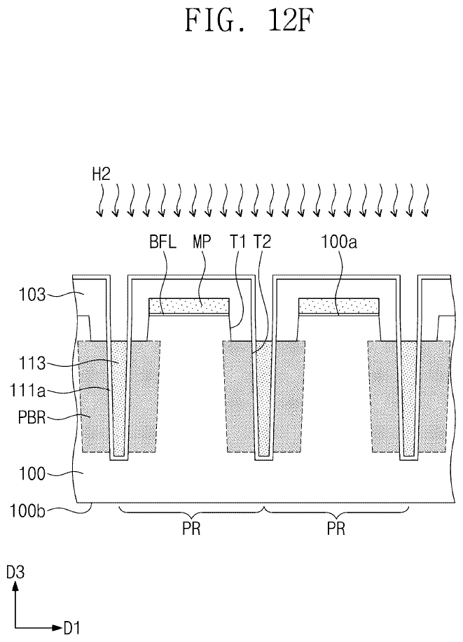

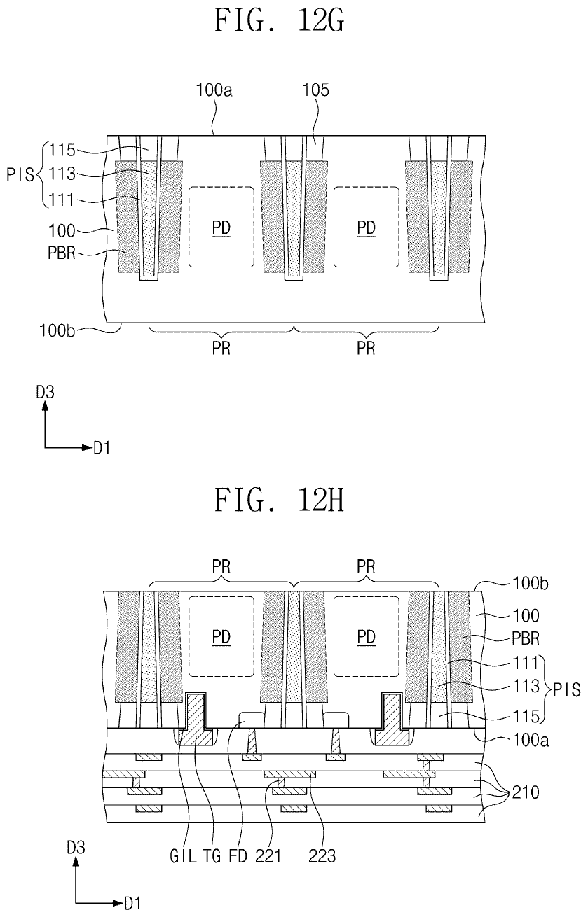

FIG. 11 is a flow chart illustrating a method of forming a pixel isolation structure that is provided in an image sensor according to an embodiment of the present inventive concept. FIGS. 12A to 12H are cross-sectional views that are taken along the line A-A′ of FIG. 3 to illustrate a method of fabricating an image sensor according to embodiments of the present inventive concept.

Referring to FIG. 12A, the semiconductor substrate 100 of the first conductivity type (e.g., p-type) may be provided. The semiconductor substrate 100 may have the first surface 100a and the second surface 100b that are opposite to each other (e.g., in the third direction D3). In an embodiment, the semiconductor substrate 100 may include a bulk silicon substrate of a first conductivity type and an epitaxial layer that is formed on the bulk silicon substrate and is of the first conductivity type. In an embodiment, the epitaxial layer may be formed by a selective epitaxial growth (SEG) process using the bulk silicon substrate as a seed, and the epitaxial layer may be doped with impurities of the first conductivity type, during the epitaxial growth process. For example, the epitaxial layer may contain p-type impurities.

In an embodiment, the semiconductor substrate 100 may be a bulk semiconductor substrate including a well of the first conductivity type. In an embodiment, the semiconductor substrate 100 may be a silicon-on-insulator (SOI) substrate, a germanium substrate, a germanium-on-insulator (GOI) substrate, or a silicon-germanium substrate.

The first trench T1 may be formed by patterning the first surface 100a of the semiconductor substrate 100. The first trench T1 may define the first and second active portions ACT1 and ACT2 in each of the pixel regions PR. The formation of the first trench T1 may include forming a buffer layer BFL and a mask pattern MP on the first surface 100a of the semiconductor substrate 100 and anisotropically etching the semiconductor substrate 100 using the mask pattern MP as an etch mask.

In an embodiment, the buffer layer BFL may be formed by performing a deposition process or a thermal oxidation process on the first surface 100a of the semiconductor substrate 100. In an embodiment, the buffer layer BFL may include a silicon oxide layer.

In an embodiment, the mask pattern MP may include a silicon nitride layer or a silicon oxynitride layer.

A device isolation insulating layer 103 may then be formed to fill the first trench T1. In an embodiment, the device isolation insulating layer 103 may be formed by thickly depositing an insulating material on the semiconductor substrate 100 having the first trench T1 formed therein. The device isolation insulating layer 103 may be formed to fill the first trench T1 and to cover the mask pattern MP.

Referring to FIGS. 11 and 12B, the second trench T2 may be formed in the semiconductor substrate 100 to define the pixel regions PR in block S10.

In an embodiment, the second trench T2 may be formed by patterning the device isolation insulating layer 103 and the first surface 100a of the semiconductor substrate 100. In an embodiment, a plurality of pixel regions (e.g., first and second pixel regions) may be arranged in a matrix shape or in the first and second directions D1 and D2 crossing each other.

For example, the second trench T2 may be formed by forming a second mask pattern on the device isolation insulating layer 103 and anisotropically etching the semiconductor substrate 100 using the second mask pattern as an etch mask.

The second trench T2 may be vertically extended from the first surface 100a of the semiconductor substrate 100 towards the second surface 100b and may expose a portion of a side surface of the semiconductor substrate 100. The second trench T2 may be formed to be deeper than the first trench T1 and to penetrate a portion of the first trench T1. In an embodiment, the second trench T2 may be a deep trench having an aspect ratio of about 10:1 to about 15:1.

When viewed in the plan view of FIG. 3, the second trench T2 may include a plurality of first regions that are extended in the first direction D1 and have a uniform width, and a plurality of second regions that are extended in the second direction D2 crossing the first direction D1 and has a uniform width.

In an embodiment in which the second trench T2 is formed by the anisotropic etching process, a width of the second trench T2 may gradually decrease as a distance from the first surface 100a of the semiconductor substrate 100 increases in a direction towards the second surface 100b. For example, the second trench T2 may have an inclined side surface. A bottom surface of the second trench T2 may be spaced apart from the second surface 100b of the semiconductor substrate 100 (e.g., in the third direction D3).

The second mask pattern may be removed, after the formation of the second trench T2.

Referring to FIGS. 11 and 12C, a doping process may be performed on an exposed surface of the semiconductor substrate in block S20.

The doping process may include a first doping process P1 and a second doping process P2. The first doping process P1 may include doping the semiconductor substrate 100 with dopants of the second conductivity type. The second doping process P2 may be performed after the first doping process P1. The second doping process P2 may include doping the semiconductor substrate 100 with the dopants of the first conductivity type. A diffusion coefficient of the dopants of the second conductivity type may be higher than a diffusion coefficient of the dopants of the first conductivity type.

In an embodiment, a preliminary thermal treatment process may be further performed between the first doping process P1 and the second doping process P2. As a result of the preliminary thermal treatment process, the dopants of the second conductivity type may be diffused into the semiconductor substrate 100.

For example, in an embodiment each of the first and second doping processes P1 and P2 may be a beam-lined ion implantation process or a plasma doping (PLAD) process. In the plasma doping process, a gaseous source material may be supplied into a process chamber. The source material may be ionized to form plasma, and then, a high biasing voltage may be applied to an electrostatic chuck on which the semiconductor substrate 100 is loaded to inject the ionized source material into the semiconductor substrate 100.

By using the plasma doping process, a uniform doping result may be provided at even a very deep level and a speed of the doping process may increase. In this embodiment, the exposed sidewall of the semiconductor substrate 100 may have a uniform doping concentration, regardless of a vertical position. For example, the doping concentrations of the dopants of the first and second conductivity types proximate to the second surface 100b of the semiconductor substrate 100 may be substantially equal to the doping concentrations of the dopants of the first and second conductivity types proximate to the first surface 100a of the semiconductor substrate 100.

In contrast, if the beam line ion implantation process is used, it may be difficult to realize a uniform doping profile along the exposed side surface of the semiconductor substrate 100 or in a vertical direction since the second trench T2 is formed to have a small width and a large depth. For example, if the beam line ion implantation process is used for the doping process, a doping concentration in the semiconductor substrate 100 may vary depending on a vertical depth. For example, the doping concentrations of the dopants of the first and second conductivity types may be higher in a region adjacent to the first surface 100a of the semiconductor substrate 100 as compared to a region adjacent to the second surface 100b of the semiconductor substrate 100.

In an embodiment, the first and second doping processes P1 and P2 may be performed using a gas phase doping (GPD) process. The GPD process may include supplying a doping gas into an exposed sidewall of the semiconductor substrate. In this embodiment, the doping gas may contain gallium (Ga) and phosphorus (P).

Referring to FIGS. 11 and 12D, an insulating liner layer 111a may be formed to cover an inner surface of the second trench T2 in block S30.

The insulating liner layer 111a may be formed to conformally cover the inner surface of the second trench T2 and a top surface of the device isolation insulating layer 103. For example, in an embodiment the insulating liner layer 111a may be deposited by a deposition method having a good step-coverage property. In an embodiment, the insulating liner layer 111a may be formed of or include at least one of silicon oxide, silicon nitride, and/or silicon oxynitride. In an embodiment, the insulating liner layer 111a may be deposited to a thickness in a range of about 30 Å to about 350 Å.

Referring to FIGS. 5, 11, and 12E, a first thermal treatment process H1 may be performed on the semiconductor substrate 100 in block S40.

In an embodiment, the first thermal treatment process H1 may be performed within a temperature range of about 600° C. to about 900° C. A process gas containing at least one of N₂, Ar, H₂, and/or O₂ may be used in the first thermal treatment process H1.

As a result of the first thermal treatment process H1, the dopants of the first and second conductivity types in the exposed sidewall of the semiconductor substrate 100 may be simultaneously diffused into the semiconductor substrate 100 in the first direction D1. Thus, when the first thermal treatment process H1 is finished, the potential barrier region PBR may be formed in the semiconductor substrate 100.

Since the dopants of the second conductivity type have a diffusion coefficient higher than the dopants of the first conductivity type, the dopants of the second conductivity type may diffuse to a farther region in the first direction D1 as compared to the dopants of the first conductivity type. For example, the dopants of the second conductivity type may be positioned in a deeper region of the semiconductor substrate 100 than the dopants of the first conductivity type. Due to the difference in diffusion coefficient between the dopants of the first and second conductivity types, the first and second potential barrier regions PBR1 and PBR2 may be formed, similar to an embodiment shown in FIG. 5.

For example, after the first thermal treatment process H1, a doping concentration of the dopants of the first conductivity type in the first potential barrier region PBR1 may be in a range of about 1×10¹⁴ ions/cm² to about 1×10¹⁶ ions/cm², and a doping concentration of the dopants of the second conductivity type in the second potential barrier region PBR2 may be in a range of about 1×10⁴ ions/cm² to about 1×10¹⁶ ions/cm².

Referring to FIGS. 11 and 12F, the filling pattern 113 may be formed to fill the second trench T2 provided with the insulating liner layer 111a in block S40. For example, the filling pattern 113 may fill an inner space of the second trench T2. In an embodiment, the filling pattern 113 may be formed of or include polysilicon. In an embodiment, the formation of the filling pattern 113 may include depositing a filling layer and etching the filling layer. In an embodiment, the filling layer may be formed in an in-situ doping manner.

In an embodiment, the filling layer may be formed by a layer-forming method (e.g., chemical vapor deposition (CVD) or atomic layer deposition (ALD) methods) having a good step coverage property. The filling layer may be formed to cover not only the top surface of the device isolation insulating layer 103 but also sidewalls and bottom portions of the insulating liner layer 111a that is formed in the second trench T2.

In an embodiment, the filling layer may be of the first conductivity type. In an embodiment in which the filling layer is formed by the deposition method, the filling layer may be doped with the dopants of the first conductivity type through an ion implantation process. For example, the filling layer may be formed in an in-situ doping manner. Alternatively, an ion implantation process may be performed, after the formation of the filling layer.

In an embodiment in which the filling layer is doped with the dopants of the first conductivity type, as described above, the filling pattern 113 to be described below may have a reduced electric resistance. Furthermore, by applying a specific voltage to the filling pattern 113 of the first conductivity type, it may be possible to reduce a dark current that may be produced by lattice defects at an interface between the semiconductor substrate 100 and the second trench T2.

In an embodiment, the filling pattern 113 may be formed by etching a portion of the filling layer that is located on the top surface of the device isolation insulating layer 103 and in an upper region of the second trench T2.

The filling pattern 113 may be formed to have a top surface that is located at a level greater than or equal to the bottom surface of the first trench T1. For example, the filling pattern 113 may be formed to fill a lower region of the second trench T2. Alternatively, the filling pattern 113 may be formed to have a top surface that is located at a level lower than the bottom surface of the first trench T1.

After the formation of the filling pattern 113, a second thermal treatment process H2 may be performed on the semiconductor substrate 100. In an embodiment, the second thermal treatment process H2 may be performed within a temperature range of about 600° C. to about 900° C. In an embodiment, a process gas containing at least one of N₂, Ar, H₂, or O₂ may be used in the second thermal treatment process H2. As a result of the second thermal treatment process H2, a void may be removed from the filling pattern 113. In addition, silicon atoms, which are located near the exposed sidewall of the semiconductor substrate 100 may be recrystallized.

Referring to FIG. 12G, an insulating gapfill layer may be formed to fill the second trench T2 provided with the filling pattern 113. A portion of the insulating gapfill layer may be used to form the insulating gap-fill pattern 115, which will be described below.

The insulating gapfill layer may be formed on the first surface 100a of the semiconductor substrate 100 to cover the insulating liner layer 111a. In an embodiment, the insulating gapfill layer may be formed of or include silicon oxide, silicon nitride, and/or silicon oxynitride.

In an embodiment, the insulating gapfill layer may be formed using a layer-forming method having a good step coverage property (e.g., a chemical vapor deposition (CVD) method or an atomic layer deposition (ALD) method). In this embodiment, the insulating gapfill layer in the second trench T2 may cover the sidewall portions of the insulating liner layer 111a and the top surface of the filling pattern 113. However, embodiments of the present disclosure are not necessarily limited thereto. For example, in an embodiment, the insulating gapfill layer may be formed using a deposition method having a poor step coverage property. For example, the insulating gapfill layer may be formed by a physical vapor deposition method.

After the deposition of the insulating gapfill layer, a planarization process may be performed to expose a top surface of the mask pattern MP. In an embodiment, the planarization process may be an etch-back process or a chemical mechanical polishing (CMP) process. The insulating liner layer 111a and the insulating gapfill layer may be planarized to form the insulating liner pattern 111, the filling pattern 113, and the insulating gap-fill pattern 115 in the second trench T2. Accordingly, the pixel isolation structure PIS may be formed in the second trench T2.

The mask pattern MP may be removed after the formation of the pixel isolation structure PIS, and then, the device isolation layer 105 may be formed in the first trench T1 by planarizing the device isolation insulating layer 103 to expose the first surface 100a of the semiconductor substrate 100. Since the planarization process is performed to expose the first surface 100a of the semiconductor substrate 100, the pixel isolation structure PIS may have a top surface that is substantially coplanar (e.g., in the third direction D3) with the top surface of the device isolation layer 105.

After the formation of the pixel isolation structure PIS, the photoelectric conversion regions PD of the second conductivity type may be formed in the semiconductor substrate 100.

The photoelectric conversion regions PD may be formed by injecting impurities into the semiconductor substrate 100 that are of the second conductivity type (e.g., n-type) which are different from the first conductivity type. The photoelectric conversion regions PD may be spaced apart from the first and second surfaces 100a and 100b of the semiconductor substrate 100.

In an embodiment, the photoelectric conversion regions PD may be formed, before the formation of the pixel isolation structure PIS.

Referring to FIG. 12H, MOS transistors constituting the readout circuits may be formed on the first surface 100a of the semiconductor substrate 100. After the formation of the MOS transistors, a thinning process may be performed on the semiconductor substrate 100.

For example, the transfer gate electrodes TG may be formed in the pixel regions PR, respectively. In an embodiment, the formation of the transfer gate electrodes TG may include patterning the semiconductor substrate 100 to form a gate recess region in each of the pixel regions PR, forming the gate insulating layer GIL to conformally cover an inner surface of the gate recess region, forming a gate conductive layer to fill the gate recess region, and patterning the gate conductive layer.

In addition, gate electrodes of readout transistors may also be formed in each of the pixel regions PR when the transfer gate electrodes TG are formed by patterning the gate conductive layer.

After the formation of the transfer gate electrodes TG, the floating diffusion regions FD may be formed in portions of the semiconductor substrate 100, each of which is located at a side of the transfer gate electrode TG. In an embodiment, the floating diffusion regions FD may be formed by an ion injection process of injecting dopants of the second conductivity type into the semiconductor substrate 100. In addition, source/drain impurity regions of the readout transistors may be formed when the floating diffusion regions FD are formed.

The interlayer insulating layers 210 and the interconnection structures may be formed on the first surface 100a of the semiconductor substrate 100.

The interlayer insulating layers 210 may be arranged to cover the transfer transistors and the logic transistors. In an embodiment, the interlayer insulating layers 210 may be formed of a material having a good gap-filling property and may be formed to have a substantially flat top surface.

The contact plugs 221 that are connected to the floating diffusion region FD or the readout transistors may be formed in the interlayer insulating layers 210. The metal lines 223 may be formed between the interlayer insulating layers 210. In an embodiment, the contact plugs 221 and the metal lines 223 may be formed of or include at least one of copper (Cu), aluminum (Al), tungsten (W), titanium (Ti), molybdenum (Mo), tantalum (Ta), titanium nitride (TiN), tantalum nitride (TaN), zirconium nitride (ZrN), tungsten nitride (WN), or alloys thereof.

A thinning process may then be performed to remove a portion of the semiconductor substrate 100 or to reduce a vertical thickness of the semiconductor substrate 100. In an embodiment, the thinning process may include grinding or polishing the second surface 100b of the semiconductor substrate 100 and performing an anisotropic or isotropic etching process. The semiconductor substrate 100 may be inverted, for the thinning process.

For example, a grinding or polishing process may be performed to remove the bulk silicon substrate from the semiconductor substrate 100 and to expose the epitaxial layer. Thereafter, an anisotropic or isotropic etching process may be performed to remove surface defects that may exist on the exposed surface of the epitaxial layer. The exposed surface of the epitaxial layer may correspond to the second surface 100b of the semiconductor substrate 100.

As a result of the thinning process on the semiconductor substrate 100, the filling pattern 113 of the pixel isolation structure PIS may be exposed to the outside proximate to the second surface 100b of the semiconductor substrate 100. The filling pattern 113 and the insulating liner pattern 111 may have surfaces that are located at substantially the same level as the second surface 100b of the semiconductor substrate 100.

Referring back to FIG. 4, the planarization insulating layer 310 may be formed on the second surface 100b of the semiconductor substrate 100. The planarization insulating layer 310 may be arranged to cover a surface of the filling pattern 113 and the second surface 100b of the semiconductor substrate 100. In an embodiment, the planarization insulating layer 310 may be formed by depositing a metal oxide layer (e.g., aluminum oxide and/or hafnium oxide).

The lattice structure 320 may be formed on the planarization insulating layer 310. The lattice structure 320 may include a light-blocking pattern and/or a low refractive pattern. A light-blocking pattern may be formed of or include at least one of metallic materials (e.g., titanium, tantalum, or tungsten). The low refractive pattern may be formed of or include a material having a refractive index that is lower than the light-blocking pattern. The low refractive pattern may be formed of an organic material and may have a refractive index in a range of about 1.1 to about 1.3. For example, the lattice structure 320 may be a polymer layer including silica nano-particles.

When viewed in a plan view, the lattice structure 320 may be extended in the first and second directions D1 and D2 to have a lattice shape. The lattice structure 320 may be overlapped with the filling pattern 113.

The protection layer 330 may be formed on the planarization insulating layer 310 to cover a surface of the lattice structure 320 conformally (e.g., to a substantially uniform thickness). In an embodiment, the protection layer 330 may be a single- or multi-layered structure including at least one of an aluminum oxide layer and a silicon carbon oxide layer.

Thereafter, the color filters 340 may be disposed on the protection layer 330 to correspond to the first and second pixel regions, respectively. In an embodiment, the color filters 340 may include blue, red, and green color filters. However, embodiments of the present inventive concept are not necessarily limited thereto.

The micro lenses 350 may be formed on the color filters 340, respectively. The micro lenses 350 may have a convex shape and may have a specific curvature radius. The micro lenses 350 may be formed of or include an optically transparent resin.

The passivation layer 360 may be conformally formed on the micro lenses 350. The passivation layer 360 may be formed of or include at least one of, for example, inorganic oxide materials.

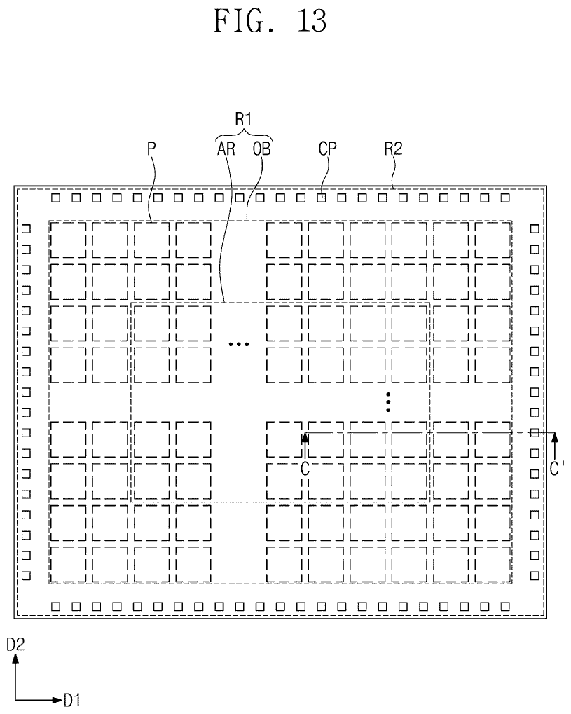

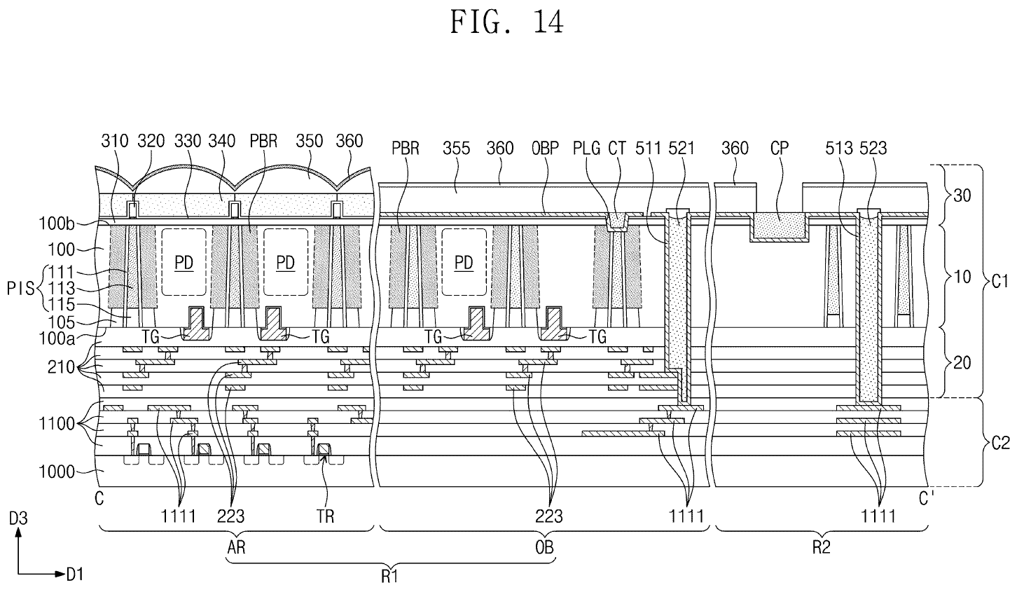

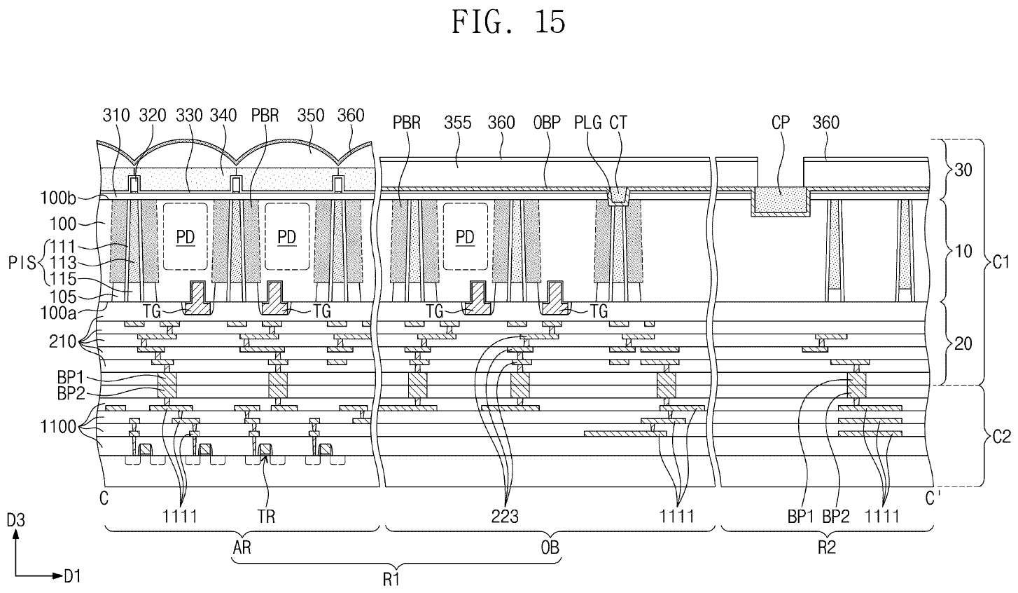

FIG. 13 is a schematic plan view illustrating an image sensor including a semiconductor device according to an embodiment of the present inventive concept. FIGS. 14 and 15 are cross-sectional views, each taken along a line C-C′ of FIG. 13, illustrating an image sensor according to an embodiment of the present inventive concept.

Referring to FIGS. 13 and 14, the image sensor may include a sensor chip C1 and a logic chip C2. The sensor chip C1 may include a pixel array region R1 and a pad region R2.

The pixel array region R1 may include a plurality of unit pixels P that are two-dimensionally arranged in two different directions (e.g., in the first and second directions D1 and D2). Each of the unit pixels P may include a photoelectric conversion device and readout devices. An electrical signal that is generated by an incident light may be output from each of the unit pixels P of the pixel array region R1.

The pixel array region R1 may include a light-receiving region AR and a light-blocking region OB. The light-blocking region OB may be arranged to enclose the light-receiving region AR, when viewed in a plan view. For example, the light-blocking region OB may be arranged to enclose the light-receiving region AR in four different directions (e.g., up, down, left, and rights directions), when viewed in a plan view. In an embodiment, reference pixels to which light is not incident may be provided in the light-blocking region OB. In this embodiment, by comparing a charge amount that is obtained from the unit pixel P in the light-receiving region AR with an amount of charges generated in the reference pixels, it may be possible to calculate a magnitude of an electrical signal generated by the unit pixel P.

A plurality of conductive pads CP that are used to input or output control signals and photoelectric signals may be disposed in the pad region R2. The pad region R2 may be provided to enclose the pixel array region R1 when viewed in a plan view. In this embodiment, the image sensor may be electrically connected to an external device. The conductive pads CP may be used to transmit electrical signals that are generated in the unit pixels P, to an external device.

The sensor chip C1 in the light-receiving region AR may comprise the same features as the image sensor described above. For example, as described above, the sensor chip C1 may include the photoelectric conversion layer 10 that is disposed between the readout circuit layer 20 and the optically-transparent layer 30 arranged in a vertical direction (e.g., the third direction D3). The photoelectric conversion layer 10 of the sensor chip C1 may include the semiconductor substrate 100, a pixel isolation structure PIS defining pixel regions, and the photoelectric conversion regions PD provided in the pixel regions, as described above. In an embodiment, the pixel isolation structure PIS may have substantially the same structure on the light-receiving region AR and on the light-blocking region OB.

The optically-transparent layer 30 may include a light-blocking pattern OBP, a back-side contact plug PLG, a contact pattern CT, an organic layer 355, and the passivation layer 360 that are disposed in the light-blocking region OB.

A portion of the pixel isolation structure PIS may be connected to the back-side contact plug PLG, in the light-blocking region OB.

For example, in the light-blocking region OB, the filling pattern 113 may be connected to the back-side contact plug PLG. The contact pattern CT and the back-side contact plug PLG may be used to apply a negative bias to the filling pattern 113. In this embodiment, it may be possible to reduce a dark current that may be generated at an interface between the pixel isolation structure PIS and the semiconductor substrate 100.

In an embodiment, the back-side contact plug PLG may have a width that is larger than a width of the pixel isolation structure PIS. The back-side contact plug PLG may be formed of or include at least one of metallic materials and/or metal nitride materials. For example, the back-side contact plug PLG may be formed of or include at least one of titanium and/or titanium nitride.

The contact pattern CT may be buried in a contact hole that the back-side contact plug PLG is formed. The contact pattern CT may include a material that is different from the back-side contact plug PLG. For example, the contact pattern CT may be formed of or include aluminum (Al).

The contact pattern CT may be electrically connected to the filling pattern 113 of the pixel isolation structure PIS. The contact pattern CT may be used to apply a negative bias to the filling pattern 113 of the pixel isolation structure PIS. In this embodiment, the negative bias may be supplied from the light-blocking region OB to the light-receiving region AR.

In the light-blocking region OB, the light-blocking pattern OBP may be continuously extended from the back-side contact plug PLG and may be disposed on a top surface of the planarization insulating layer 310. For example, the light-blocking pattern OBP may be formed of or include the same material as the back-side contact plug PLG. The light-blocking pattern OBP may be formed of or include at least one of metallic materials and/or metal nitride materials. For example, the light-blocking pattern OBP may be formed of or include at least one of titanium and/or titanium nitride. The light-blocking pattern OBP may not be extended to the light-receiving region AR of the pixel array region R1.

The light-blocking pattern OBP may prevent light from being incident into the photoelectric conversion regions PD that are disposed in the light-blocking region OB. The photoelectric conversion regions PD in the reference pixels of the light-blocking region OB may be configured to output a noise signal, not a photoelectric signal. The noise signal may be produced by electrons, which are generated by heat or a dark current.

In the light-blocking region OB, the organic layer 355 and the passivation layer 360 may be disposed on the light-blocking pattern OBP. In an embodiment, the organic layer 355 may be formed of or include the same material as the micro lenses 350.

In the light-blocking region OB, a first penetration conductive pattern 511 may be arranged to penetrate the semiconductor substrate 100 and may be electrically connected to the metal lines 223 of the readout circuit layer 20 and an interconnection structure 1111 of the logic chip C2. The first penetration conductive pattern 511 may have a first bottom surface and a second bottom surface that are located at different levels. A first gapfill pattern 521 may be disposed in the first penetration conductive pattern 511. In an embodiment, the first gapfill pattern 521 may be formed of or include at least one of low refractive materials and may have an insulating property.

In the pad region R2, the conductive pads CP may be disposed on the second surface 100b of the semiconductor substrate 100. The conductive pads CP may be buried in the semiconductor substrate 100 and proximate to the second surface 100b. In an embodiment, the conductive pads CP may be disposed in pad trenches that are formed in the second surface 100b of the semiconductor substrate 100 and are located in the pad region R2. In an embodiment, the conductive pads CP may be formed of or include at least one of metallic materials (e.g., aluminum, copper, tungsten, titanium, tantalum, or alloys thereof). In a mounting process of an image sensor, bonding wires may be bonded to the conductive pads CP. The conductive pads CP may be electrically connected to an external device through the bonding wires.

In the pad region R2, a second penetration conductive pattern 513 may be arranged to penetrate the semiconductor substrate 100 and may be electrically connected to the interconnection structure 1111 of the logic chip C2. The second penetration conductive pattern 513 may be extended to a region on the second surface 100b of the semiconductor substrate 100 and may be electrically connected to the conductive pad CP. A portion of the second penetration conductive pattern 513 may cover bottom and side surfaces of the conductive pads CP. A second gapfill pattern 523 may be disposed in the second penetration conductive pattern 513. The second gapfill pattern 523 may be formed of or include at least one of low refractive materials and may have an insulating property. In the pad region R2, the pixel isolation structures PIS may be arranged around the second penetration conductive pattern 513.

The logic chip C2 may include a logic semiconductor substrate 1000, logic circuits TR, interconnection structures 1111, and logic interlayer insulating layers 1100. The interconnection structures 1111 may be connected to the logic circuits TR. The uppermost layer of the logic interlayer insulating layers 1100 may be bonded to the readout circuit layer 20 of the sensor chip C1. The logic chip C2 may be electrically connected to the sensor chip C1 through first and second penetration conductive patterns 511 and 513.

In an embodiment, the sensor and logic chips C1 and C2 are illustrated to be electrically connected to each other through the first and second penetration conductive patterns 511 and 513. However, embodiments of the present inventive concept are not necessarily limited thereto.

Referring to FIG. 15, in an embodiment the first and second penetration conductive patterns 511 and 513 shown in an embodiment of FIG. 14 may be omitted. Bonding pads are disposed in the uppermost metal layers of the sensor and logic chips C1 and C2. The bonding pads may be directly bonded to each other to electrically connect the sensor chip C1 to the logic chip C2.

For example, the sensor chip C1 of the image sensor may include first bonding pads BP1 disposed in the uppermost metal layer of the readout circuit layer 20, and the logic chip C2 may include second bonding pads BP2 disposed in the uppermost metal layer of the interconnection structure 1111. In an embodiment, the first and second bonding pads BP1 and BP2 may be formed of or include at least one of, for example, tungsten (W), aluminum (Al), copper (Cu), tungsten nitride (WN), tantalum nitride (TaN), or titanium nitride (TiN).

The first bonding pads BP1 of the sensor chip C1 and the second bonding pads BP2 of the logic chip C2 may be electrically connected to each other by a hybrid bonding method. The hybrid bonding method may mean a method of bonding two materials of the same kind at an interface therebetween (e.g., through a fusion process). For example, in an embodiment in which the first and second bonding pads BP1 and BP2 are formed of copper (Cu), the first and second bonding pads BP1 and BP2 may be physically and electrically connected to each other in a Cu—Cu bonding manner. In addition, insulating layers of the sensor and logic chips C1 and C2 may be bonded to each other in a dielectric-dielectric bonding manner.

According to an embodiment of the present inventive concept, an image sensor may include a first potential barrier region of a first conductivity type, a photoelectric conversion region of a second conductivity type, and a second potential barrier region that is provided therebetween and has the second conductivity type. The second potential barrier region may be used to optimize a potential profile in a pixel region. Thus, even when an image sensor is scaled down, the image sensor may be fabricated to have an increased full well capacity (FWC) property. Accordingly, it may be possible to realize an image sensor with an increased dynamic range property.

In a method of fabricating an image sensor according to an embodiment of the present inventive concept, by using a difference in diffusion coefficients between dopants of the first and second conductivity types, it may be possible to form the first and second potential barrier regions at the same time. This may make it possible to simplify the fabrication process and to increase performance of the image sensor.

While example embodiments of the present inventive concept have been particularly shown and described, it will be understood by one of ordinary skill in the art that variations in form and detail may be made therein without departing from the spirit and scope of the present inventive concept.

What is claimed is:

1. A method of fabricating an image sensor, comprising:
providing a semiconductor substrate;
forming a trench in the semiconductor substrate to define pixel regions;
doping the trench with dopants of a first conductivity type;
doping the trench with dopants of a second conductivity type;
forming an insulating liner pattern in the trench;
performing a first thermal treatment process on the semiconductor substrate; and
forming a filling pattern to fill an inner space of the trench,
wherein a diffusion coefficient of the dopants of the first conductivity type is greater than a diffusion coefficient of the dopants of the second conductivity type, and
the first thermal treatment process diffuses the dopants of the first and second conductivity types into the semiconductor substrate simultaneously.

2. The method of claim 1, wherein:
the diffusing of the dopants into the semiconductor substrate forms a first potential barrier region and a second potential barrier region; and
the second potential barrier region is located between the insulating liner pattern and the first potential barrier region.

3. The method of claim 2, wherein:
a doping concentration of the dopants of the first conductivity type has a highest value in the first potential barrier region; and
a doping concentration of the dopants of the second conductivity type has a highest value in the second potential barrier region.

4. The method of claim 1, further comprising performing a preliminary thermal treatment process between the doping of the dopants of the first conductivity type and the doping of the dopants of the second conductivity type.

5. The method of claim 1, wherein the doping the trench with the dopants of the first and second conductivity types are performed using one process selected from a plasma doping process, a beam line ion implantation process, and a gas phase doping process.

6. The method of claim 1, further comprising performing a second thermal treatment process after the forming of the filling pattern.

7. The method of claim 1, wherein:
the dopants of the first conductivity type comprise phosphorus (P); and
the dopants of the second conductivity type comprise gallium (Ga).

8. The method of claim 1, further comprising forming photoelectric conversion regions in the pixel regions of the semiconductor substrate, respectively, after the forming of the filling pattern.

9. The method of claim 8, further comprising forming a transfer gate electrode, after the forming of the photoelectric conversion regions,
wherein the transfer gate electrode comprises a first portion disposed directly on a first surface of the semiconductor substrate and a at least one second portion that extends from the first portion towards a second surface of the semiconductor substrate and is located in the semiconductor substrate.

10. The method of claim 1, wherein the forming of the filling pattern comprises:
depositing a filling layer and etching the filling layer; and
the depositing of the filling layer is performed in an in-situ manner.

11. An image sensor, comprising:
a semiconductor substrate including first and second potential barrier regions and a photoelectric conversion region; and
a pixel isolation structure disposed in the semiconductor substrate to define a plurality of pixel regions,
wherein the pixel isolation structure comprises:
a filling pattern vertically penetrating the semiconductor substrate; and
an insulating liner pattern disposed between the filling pattern and the semiconductor substrate,
the first potential barrier region is of a first conductivity type,
the second potential barrier region and the photoelectric conversion region are of a second conductivity type,
the first potential barrier region is positioned closer to the pixel isolation structure than the second potential barrier region, and
dopants of the first conductivity type have a diffusion coefficient that is less than dopants of the second conductivity type.

12. The image sensor of claim 11, wherein:
the first and second potential barrier regions are located between the pixel isolation structure and the photoelectric conversion region; and
the second potential barrier region is positioned closer to the photoelectric conversion region than the first potential barrier region.

13. The image sensor of claim 11, wherein:
the dopants of the first conductivity type comprise gallium (Ga); and
the dopants of the second conductivity type comprise phosphorus (P).

14. The image sensor of claim 11, wherein the dopants of the first conductivity type have a highest doping concentration in the first potential barrier region.

15. The image sensor of claim 11, wherein the dopants of the second conductivity type have a highest doping concentration in the second potential barrier region.

16. The image sensor of claim 11, further comprising a transfer gate electrode including a first portion disposed directly on a first surface of the semiconductor substrate, and a second portion that extends from the first portion towards a second surface of the semiconductor substrate and is located in the semiconductor substrate.

17. The image sensor of claim 16, wherein the transfer gate electrode includes a plurality of the second portions.

18. The image sensor of claim 11, wherein:
the pixel isolation structure further comprises an insulating gap-fill pattern on the filling pattern; and
the insulating gap-fill pattern has a top surface that is coplanar with a top surface of the insulating liner pattern.

19. An image sensor, comprising:
a semiconductor substrate having a first surface and a second surface that are opposite to each other, and comprising a light-receiving region, a light-blocking region, and a pad region;
a pixel isolation structure disposed in the semiconductor substrate and in the light-receiving region and the light-blocking region to define a plurality of pixel regions, the pixel isolation structure comprising a filling pattern vertically penetrating the semiconductor substrate, an insulating liner pattern interposed between the filling pattern and the semiconductor substrate, and an insulating gap-fill pattern on the filling pattern;
a transfer gate electrode including a first portion disposed directly on the first surface of the semiconductor substrate, and at least one second portion that extends from the first portion towards the second surface of the semiconductor substrate and is located in the semiconductor substrate;
photoelectric conversion regions disposed in the light-receiving region and the light-blocking region and in the plurality of pixel regions of the semiconductor substrate;
a back-side contact plug disposed in a portion of the light-blocking region and positioned adjacent to the second surface of the semiconductor substrate and in direct contact with a portion of the filling pattern;
a conductive pad disposed in the pad region and on the second surface of the semiconductor substrate;
color filters disposed on the second surface of the semiconductor substrate to correspond to the plurality of pixel regions; and
micro lenses on the color filters,
wherein the semiconductor substrate comprises a first potential barrier region of a first conductivity type and a second potential barrier region of a second conductivity type, and
a diffusion coefficient of dopants of the first conductivity type is less than a diffusion coefficient of dopants of the second conductivity type.

20. The image sensor of claim 19, wherein:
the first and second potential barrier regions are located between the pixel isolation structure and the photoelectric conversion regions; and
the first potential barrier region is positioned closer to the pixel isolation structure than the second potential barrier region.
